(19) United States
(12) Patent Application Publication
(10) Pub. No.: US 2015/0171286 A1
(43) Pub. Date: Jun. 18, 2015

(54) LIGHT-EMITTING DIODE PACKAGE AND METHOD FOR MANUFACTURING THE SAME

(71) Applicant: LEXTAR ELECTRONICS CORPORATION, Hsinchu (TW)

(72) Inventor: Yu-Hsin LU, Changhua County (TW)

(73) Assignee: LEXTAR ELECTRONICS CORPORATION, Hsinchu (TW)

(21) Appl. No.: 14/243,847

(22) Filed: Apr. 2, 2014

(30) Foreign Application Priority Data
Dec. 17, 2013 (TW) 102146528

(51) Int. Cl. H01L 33/50; H01L 27/15; H01L 33/00

(52) U.S. Cl. CPC H01L 33/505; H01L 33/005; H01L 27/153

(57) ABSTRACT

The present disclosure provides a light-emitting diode package, including: a carrier; a light-emitting diode chip disposed over the carrier; and a fluorescent sheet covering the light-emitting diode chip, wherein the fluorescent sheet has a recess corresponding to the light-emitting diode chip, wherein the light-emitting diode chip is placed in the recess, and light-emitting surfaces of the light-emitting diode chip are covered by the fluorescent sheet. The present disclosure also provides a method for manufacturing a light-emitting diode package.

### CROSS REFERENCE TO RELATED APPLICATIONS

This application claims priority of Taiwan Patent Application No. 102146528, filed on Dec. 17, 2013, the entirety of which is incorporated by reference herein.

### BACKGROUND

1. Technical Field

The disclosure relates to a light-emitting diode package and a method for manufacturing the same, and in particular to a light-emitting diode package having a fluorescent sheet with a recess and a method for manufacturing the same.

2. Description of the Related Art

A conventional light-emitting diode has a P/N junction, and the light-emitting diode may emit light when electric voltage is applied to the P/N junction. The light-emitting diode is widely used in various applications such as indicators, shop signs, indoor illumination, outdoor illumination and back-lighted devices. Since the light-emitting diode (LED) has advantages such as small volume, long lifetime, low power consumption and high brightness, the light-emitting diode is gradually replacing the conventional light bulb and becoming the most important illumination device now.

In the conventional packaging process, the die mount adhesive is formed on the light-emitting diode chip. However, since the light emitting qualities of the light-emitting diode packages may vary even when manufactured by the same adhesive dispensing process, the light emitting quality can be determined only after the packaging process. Therefore, defective products must be discarded after completing the packaging process, which results in unnecessary wastes and increase the manufacturing cost.

Therefore, a manufacturing method which may determine the light-emitting quality of the light-emitting diode in the packaging processes is needed.

### SUMMARY

The present disclosure provides a light-emitting diode package, including: a carrier; a light-emitting diode chip disposed over the carrier; and a fluorescent sheet covering the light-emitting diode chip, wherein the fluorescent sheet has a recess corresponding to the light-emitting diode chip, wherein the light-emitting diode chip is placed in the recess, and light-emitting surfaces of the light-emitting diode chip are covered by the fluorescent sheet.

The present disclosure also provides a method for manufacturing a light-emitting diode package, including: providing a fluorescent powder-blended ceramic sheet; etching the fluorescent powder-blended ceramic sheet to form a plurality of recesses in the fluorescent powder-blended ceramic sheet; dispensing a die mount adhesive into the plurality of recesses; and providing a plurality of light-emitting diode chips, wherein the plurality of light-emitting diode chips are placed in the plurality of recesses, and light-emitting surfaces of the plurality of light-emitting diode chips are covered by the plurality of recesses.

A detailed description is given in the following embodiments with reference to the accompanying drawings.

### BRIEF DESCRIPTION OF THE DRAWINGS

The disclosure may be more fully understood by reading the subsequent detailed description and examples with references made to the accompanying drawings, wherein:

FIGS. 1-7 are cross-sectional views of a light-emitting diode package and a light-emitting device at various manufacturing stages in accordance with some embodiments of the present disclosure; and

FIGS. 8-10 are cross-sectional views of a light-emitting device at various manufacturing stages in accordance with other embodiments of the present disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In this specification, expressions such as “overlying the substrate”, “above the layer”, or “on the film” simply denote a relative positional relationship with respect to the surface of a base layer, regardless of the existence of intermediate layers. Accordingly, these expressions may indicate not only the direct contact of layers, but also, a non-contact state of one or more laminated layers. It is noted that in the accompanying drawings, like and/or corresponding elements are denoted to by like reference numerals.

In this specification, relative expressions are used. For example, “lower”, “bottom”, “higher” or “top” are used to describe the position of an element relative to another. It should be appreciated that if a device is flipped upside down, an element at “lower” side will become an element at “higher” side.

The terms “about” and “substantially” typically means +/−20% of the stated value, more typically +/−10% of the stated value and even more typically +/−5% of the stated value. The stated value of the present disclosure is an approximate value. When there is no specific description, the stated value includes the meaning of “about” or “substantially”.

To solve the issue that the light emitting quality can be determined only after completing the packaging process using the adhesive dispensing processes, the present disclosure utilizes a fluorescent sheet to replace the adhesive dispensing process and places the light-emitting diode chip in a recess to increase the conversion efficiency of the laterally emitted light. The manufacturing method of the present disclosure may ensure that all the final light-emitting diode packages have the same light emitting quality when the fluorescent sheet is manufactured, which in turn, increases the yield and reduces the cost of the defective products.

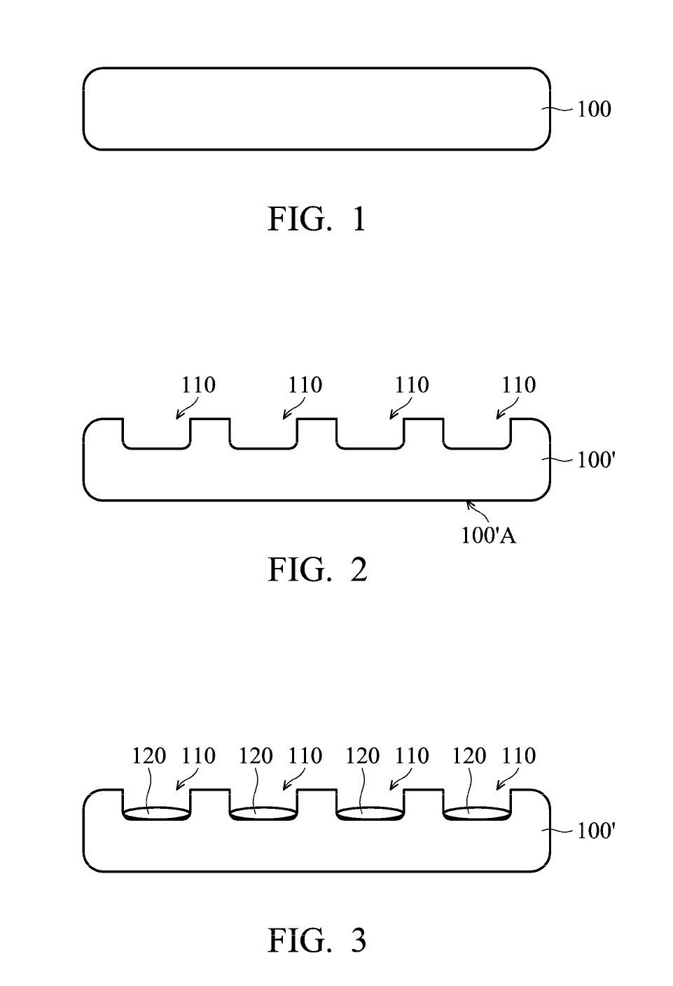

First, referring to FIG. 1, a fluorescent sheet 100 is provided. In some embodiments of the present disclosure, the fluorescent sheet 100 may include, but is not limited to, a fluorescent powder-blended ceramic sheet (referred to as a ceramic fluorescent sheet). The ceramic fluorescent sheet may be formed by sintering the fluorescent powder and the ceramic powder at high temperature. The examples of ceramic powders include silicon oxide, aluminum oxide or any other suitable materials. The examples of fluorescent powders include yttrium aluminium garnet (Y₃Al₅O₁₂, YAG), lutetium aluminium garnet (Lu₃Al₅O₁₂, LuAG), silicate, nitride or any other suitable fluorescent powders. The fluorescent powders may convert the light emitted by the light-emitting diode chip into white light. Besides, the yield may be further increased since the manufacturing of the ceramic fluorescent sheet has high reliability. The ceramic fluorescent sheet has high structural strength and excellent humidity resistance, therefore the ceramic fluorescent sheet has excellent performance under the high-temperature and high-humidity circumstance.

Next, referring to FIG. 2, the fluorescent sheet 100 is etched to form four recesses 110 in the fluorescent sheet 100. The recesses 110 are used to place light-emitting diode bare chips. The surface area of the recesses 110 is greater than or equal to the light-emitting diode bare chips, and the depth of the recesses 110 is smaller than the thickness of the light-emitting diode bare chips. In the following, the fluorescent sheet with the recesses 110 is referred to as the fluorescent sheet 100′. The recesses 110 may be formed by mechanical methods such as drilling, laser cutting, a dry etching process or a wet etching process. Note that although FIG. 2 merely illustrates the fluorescent sheet 100′ with four recesses 110, the number of the recesses 110 should not be limited to this. The fluorescent sheet 100′ may have other amounts of recesses 110, which will be described in the following. Besides, the main surface of the fluorescent sheet 100′ is preferably a planar surface.

Next, as illustrated in FIG. 3, a die mount adhesive 120 is dispensed into the recesses 110. The die mount adhesive 120 may include, but is not limited to, epoxy resin or silica gel and is preferably a die mount adhesive with good transparency.

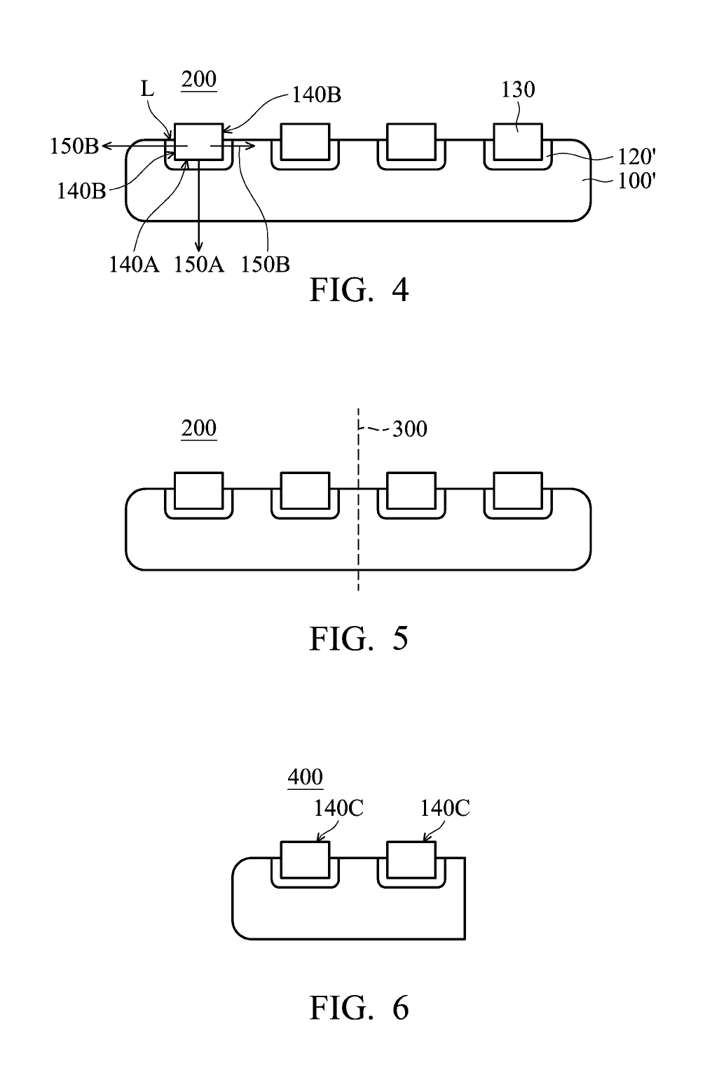

Next, referring to FIG. 4, light-emitting diode chips 130 are provided and placed into each of the recesses 110 such that the light-emitting surfaces of the light-emitting diode chips 130 are covered by the recesses 110 and the light-emitting diode package 200 is completed. The light-emitting surfaces of the light-emitting diode chip 130 include a main light-emitting surface 140A and lateral light-emitting surfaces 140B. The die mount adhesive 120 is pressed and deformed by the light-emitting diode chip 130 and is disposed between the recess 110 and the light-emitting diode chip 130. In the following, the deformed die mount adhesive is referred to as the die mount adhesive 120′.

The light-emitting diode chip 130 may include flip-chip light-emitting diode chip. The light-emitting diode chip 130 may include at least a P-type semiconductor layer, an active layer and a N-type semiconductor layer, and the active layer is disposed between the P-type semiconductor layer and the N-type semiconductor layer. Besides, a metal reflective layer may be optionally formed over the side of the light-emitting diode chip 130 opposite to the fluorescent sheet 100′. The material of the metal reflective layer may include, but is not limited to, Al, Ag, Ni, Ph, Pd, Pt, Ru, Au or a combination thereof. The P-type semiconductor layer and the N-type semiconductor layer may include, but is not limited to, group III-V semiconductor materials such as GaN material of group III-V semiconductor, which may be represented as AlₓGa_{y}In_{(1-x-y)}N, wherein 0≦x≦1 and 0≦y≦1. The light emitted by the light-emitting diode chip 130 is preferably blue light or UV light, however the light emitted by the light-emitting diode chip 130 may be other light with a suitable wavelength. The light emitted by the light-emitting diode chip 130 includes the light 150A emitted from the main light-emitting surface 140A of the light-emitting diode chip 130 and the light 150B emitted from the lateral light-emitting surfaces 140B of the light-emitting diode chip 130. When the light emitted by the light-emitting diode chip 130 is blue light or UV light, the suitable fluorescent sheet 100′ may be selected such that the final mixed light of the light-emitting diode package 200 is white light. In some embodiments of the present disclosure, the thickness of the light-emitting diode chip 130 may range from about 70 μm to 90 μm. Besides, the thickness of the light-emitting diode chip 130 is greater than the depth of the recess 110 by a length L. The length L may range from about 1 μm to 20 μm, preferably from about 1 μm to 10 μm. The subsequent mounting process for mounting the light-emitting diode package 200 onto a carrier may be facilitated when the thickness of the light-emitting diode chip 130 is greater than the depth of the recess 110.

Since the fluorescent sheet with good light conversion efficiency may be sorted out when the fluorescent sheet is manufactured and all of the light-emitting diode chips in the light-emitting diode package are covered by the same fluorescent sheet, it assures that all the final light-emitting diodes manufactured from this light-emitting diode package have the same light-emitting quality. Color tests of the light after conversion by the fluorescent sheet may be performed by the color test equipment to sort out the fluorescent sheet with good light conversion efficiency and good quality. Besides, since the light emitting quality of the light-emitting diode need not be determined after the packaging process as the conventional packaging process with adhesive dispensing step, the manufacturing method of the present disclosure is cost-effective and may increase the yield.

Besides, if the fluorescent sheet merely covers the main light-emitting surface of the light-emitting diode chip, the light emitted from the lateral light-emitting surfaces of the light-emitting diode chip cannot be converted to white light by the fluorescent sheet, which in turn, decreases the light conversion efficiency and results in non-uniformity of the emitted light. For example, the light emitted from the main light-emitting surface of the light-emitting diode chip is white light, whereas the light emitted from the lateral light-emitting surfaces of the light-emitting diode chip is blue light. Therefore, the present disclosure places the light-emitting diode chip in the recess of the fluorescent sheet to ensure that all the light-emitting surfaces of the light-emitting diode chip are covered by the recess of the fluorescent sheet to maintain high light conversion efficiency and prevent the non-uniformity of the emitted light. For example, as illustrated in FIG. 4, since all of the main light-emitting surface 140A and the lateral light-emitting surfaces 140B of the light-emitting diode chip 130 are covered by the recess 110 of the fluorescent sheet 100′, the light 150A emitted from the main light-emitting surface 140A of the light-emitting diode chip 130 and the light 150B emitted from the lateral light-emitting surfaces 140B of the light-emitting diode chip 130 may be converted to white light by the fluorescent sheet 100′. Therefore, the light-emitting diode package of the present disclosure may maintain high light conversion efficiency and prevent the non-uniformity of the emitted light.

Next, referring to FIGS. 5-6, a cutting process 300 is performed to cut the light-emitting diode package 200 to form a plurality of light-emitting diode units 400. The cutting process 300 may include, but is not limited to, laser cutting, lithography and etching, wheel cutting or a combination thereof.

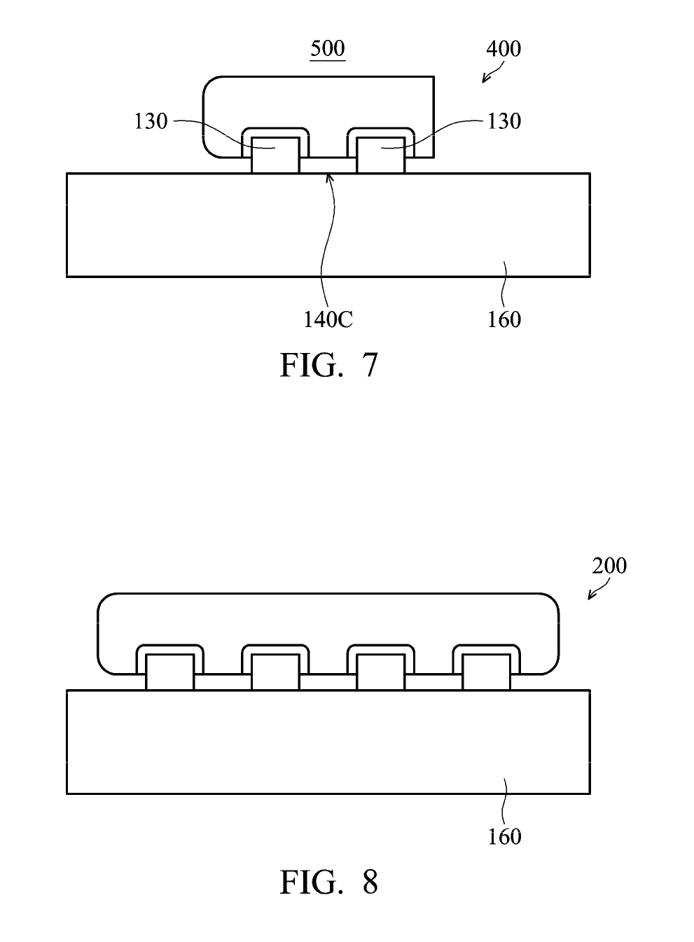

Next, referring to FIG. 7, the light-emitting diode unit 400 is mounted onto a carrier 160 to form a light-emitting device 500. The light-emitting diode unit 400 is electrically connected to the carrier 160. The carrier 160 may include, but is not limited to, die-mount substrate or a lead frame. The die-mount substrate may include, but is not limited to, a rigid printed circuit board, a high thermal conductivity Al substrate, a ceramic substrate, a flexible printed circuit board or a metal composite substrate. In some embodiments of the present disclosure, a die mount adhesive (not shown) may be used to mount the light-emitting diode unit 400 onto the carrier 160. For example, the die mount adhesive (not shown) is first formed on a predetermined region of the carrier 160 for disposing the light-emitting diode unit 400, then the light-emitting diode unit 400 is disposed over the die mount adhesive to mount the light-emitting diode unit 400 onto the carrier 160. This die mount adhesive may include, but is not limited to, epoxy resin or silica gel, and the epoxy resin may include, but is not limited to, an epoxy resin blended with silver powder. In other embodiments of the present disclosure, the light-emitting diode unit 400 may be mounted onto the carrier 160 by eutectic bonding. For example, an eutectic metal layer (not shown) may be formed over the surface 140C of the light-emitting diode chip 130 in the light-emitting diode unit 400, then the light-emitting diode unit 400 may be eutectically bonded to the carrier 160 with the surface 140C facing toward the carrier 160 and a heating process may be performed to mount the light-emitting diode unit 400 onto the carrier 160.

Note that although FIGS. 6-7 merely illustrate that the light-emitting diode unit 400 has two light-emitting diode chips 130, the light-emitting diode unit 400 may have more light-emitting diode chips 130. The number of light-emitting diode chips 130 should not be limited to FIGS. 6-7. This will be described in the following.

Besides, although the light-emitting diode package 200 is cut first to form the plurality of light-emitting diode units 400 and then the light-emitting diode unit 400 is mounted onto the carrier 160 to form the light-emitting device 500 in the aforementioned embodiments, the light-emitting diode package 200 may also be mounted onto the carrier 160 first, then a cutting process may be performed to form the light-emitting device 500 in other embodiments, as shown in FIGS. 8-10.

Referring to FIG. 8, the light-emitting diode package 200 of FIG. 4 is mounted onto the carrier 160. The light-emitting diode package 200 is electrically connected to the carrier 160. The light-emitting diode package 200 may be mounted onto the carrier 160 by the aforementioned die mount adhesive or eutectic bonding.

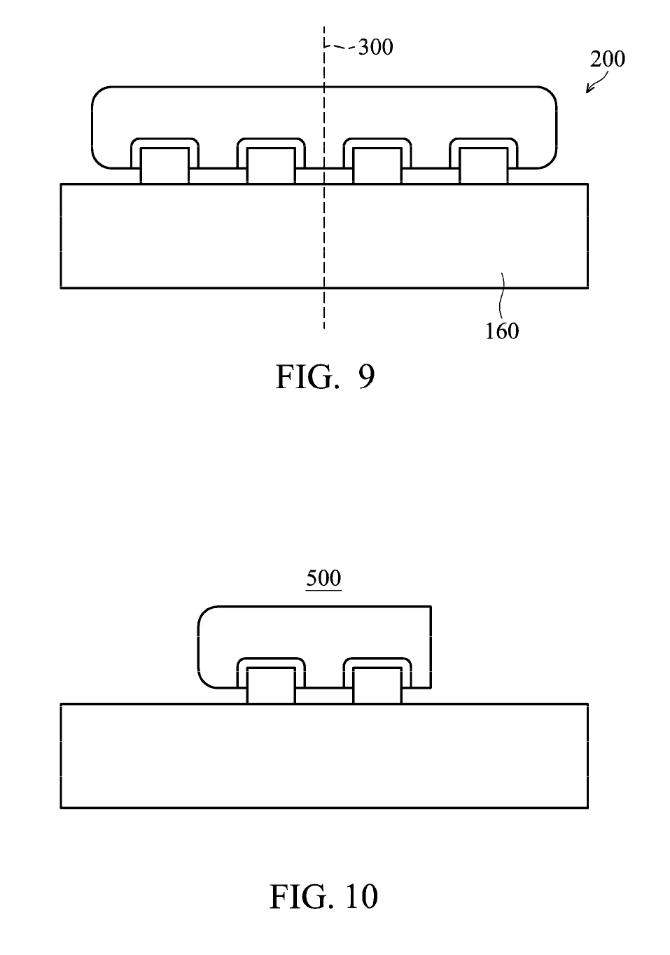

Next, as illustrated in FIGS. 9-10, the cutting process 300 is performed to cut the light-emitting diode package 200 and the carrier 160 to form the plurality of light-emitting device 500. The cutting process 300 may include, but is not limited to, laser cutting, lithography and etching, wheel cutting or a combination thereof.

Note that although FIGS. 2-5 and 8-9 merely illustrate the light-emitting diode package 200 having four recesses 110 and light-emitting diode chips 130, the light-emitting diode package 200 may have more than four recesses 110 and light-emitting diode chips 130. The number of recesses 110 and light-emitting diode chips 130 should not be limited to the embodiments shown in FIGS. 2-5 and 8-9. Besides, although FIGS. 7 and 10 merely illustrates the light-emitting device 500 having two light-emitting diode chips 130, the light-emitting device 500 may also have more light-emitting diode chips 130 and it should not be limited to the embodiments shown in FIGS. 7 and 10.

Besides, in one embodiment of the present disclosure, only one recess is formed in one fluorescent sheet and the aforementioned manufacturing processes except the cutting process are performed to directly accomplish the light-emitting device. In this embodiment, the light-emitting device has only one light-emitting diode chip.

In summary, the present disclosure places the light-emitting diode chip in the recess of the fluorescent sheet to replace the adhesive dispensing process, therefore the manufacturing method provided in the present disclosure may ensure that all the final light-emitting diode packages have the same light-emitting quality when the fluorescent sheet is manufactured, which in turn, reduces the cost of the defective products. Besides, the present disclosure places the light-emitting diode chip in the recess of the fluorescent sheet to ensure that all the light-emitting surfaces of the light-emitting diode chip are covered by the recess of the fluorescent sheet to maintain high light conversion efficiency and prevent the non-uniformity of the emitted light.

Although some embodiments of the present disclosure and their advantages have been described in detail, it should be understood that various changes, substitutions and alterations can be made herein without departing from the spirit and scope of the disclosure as defined by the appended claims. For example, it will be readily understood by those skilled in the art that many of the features, functions, processes, and materials described herein may be varied while remaining within the scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A light-emitting diode package, comprising:
a carrier;
a light-emitting diode chip disposed over the carrier; and
a fluorescent sheet covering the light-emitting diode chip, wherein the fluorescent sheet has a recess corresponding to the light-emitting diode chip, wherein the light-emitting diode chip is placed in the recess, and light-emitting surfaces of the light-emitting diode chip are covered by the fluorescent sheet.

2. The light-emitting diode package as claimed in claim 1, wherein the fluorescent sheet comprises a ceramic fluorescent sheet.

3. The light-emitting diode package as claimed in claim 2, wherein a thickness of the light-emitting diode chip is greater than a depth of the recess by 1 μm-10 μm.

4. The light-emitting diode package as claimed in claim 3, wherein the carrier comprises a die-mount substrate or a lead frame.

5. The light-emitting diode package as claimed in claim 4, wherein the die-mount substrate comprises a rigid printed circuit board, a high thermal conductivity Al substrate, a ceramic substrate, a flexible printed circuit board or a metal composite substrate.

6. The light-emitting diode package as claimed in claim 5, further comprising a die mount adhesive disposed between the recess and the light-emitting diode chip.

7. A method for manufacturing a light-emitting diode package, comprising:
providing a fluorescent powder-blended ceramic sheet;
etching the fluorescent powder-blended ceramic sheet to form a plurality of recesses in the fluorescent powder-blended ceramic sheet;
dispensing a die mount adhesive into the plurality of recesses; and
providing a plurality of light-emitting diode chips, wherein the plurality of light-emitting diode chips are placed in the plurality of recesses, and light-emitting surfaces of the plurality of light-emitting diode chips are covered by the plurality of recesses.

8. The method for manufacturing the light-emitting diode package as claimed in claim 7, further comprising mounting the light-emitting diode package onto a carrier.

9. The method for manufacturing the light-emitting diode package as claimed in claim 7, further comprising:
cutting the light-emitting diode package to form a plurality of light-emitting diode units; and
mounting the plurality of light-emitting diode units onto a carrier.

10. The method for manufacturing the light-emitting diode package as claimed in claim 9, wherein the cutting comprises laser cutting, lithography and etching, wheel cutting or a combination thereof.

11. The method for manufacturing the light-emitting diode package as claimed in claim 7, wherein the form of the plurality of recesses comprises a dry etching process or a wet etching process.

12. The method for manufacturing the light-emitting diode package as claimed in claim 11, wherein a thickness of the light-emitting diode chip is greater than a depth of the recess by 1 μm-10 μm.

13. The method for manufacturing the light-emitting diode package as claimed in claim 12, wherein the carrier comprises a die-mount substrate or a lead frame.

14. The method for manufacturing the light-emitting diode package as claimed in claim 13, wherein the die-mount substrate comprises a rigid printed circuit board, a high thermal conductivity Al substrate, a ceramic substrate, a flexible printed circuit board or a metal composite substrate.
